(19) United States
(12) Patent Application Publication
(10) Pub. No.: US 2023/0311692 A1
(43) Pub. Date: Oct. 5, 2023

(54) TECHNOLOGY FOR MONITORING A CONTACT BETWEEN CHARGING CONDUCTORS FOR CHARGING AN ELECTRIC VEHICLE

(71) Applicant: Phoenix Contact GmbH & Co. KG, Blomberg (DE)

(72) Inventor: Peter SCHOLZ, Brakel (DE)

(21) Appl. No.: 18/004,181

(22) PCT Filed: Jul. 8, 2021
(86) PCT No.: PCT/EP2021/068953

§ 371 Date: Jan. 4, 2023

(30) Foreign Application Priority Data
Jul. 9, 2020 (BE) 2020/5509

(51) Int. Cl. B60L 53/62; B60L 53/16; B60L 53/18

(52) U.S. Cl. CPC B60L 53/62; B60L 53/18; B60L 53/16

(57) ABSTRACT

A device for monitoring a contact between charging conductors of a charging station for charging an electric vehicle includes: a signal generator for outputting an alternating test signal at the charging conductors; and an evaluation unit for determining, based upon the test signal, whether an electrically conductive contact exists between the charging conductors.

### CROSS-REFERENCE TO PRIOR APPLICATIONS

This application is a U.S. National Phase application under 35 U.S.C. § 371 of International Application No. PCT/EP2021/068953, filed on Jul. 8, 2021, and claims benefit to Belgian Patent Application No. BE 2020/5509, filed on Jul. 9, 2020. The International Application was published in German on Jan. 13, 2022 as WO/2022/008640 under PCT Article 21(2).

### FIELD

The invention relates to a technology for monitoring a contact—preferably a short circuit—between charging conductors of a charging station for charging an electric vehicle. In particular, a device for monitoring a contact between charging conductors, a charging station with such a device, and a charging plug with such a device are disclosed, without being limited thereto.

### BACKGROUND

In the prior art, methods for detecting a short circuit are known which charge a capacitor with a test voltage and apply the test voltage of the capacitor to the charging cable. DE 10 2010 042 750 A1 describes such a method.

However, such conventional methods are complex and cost-intensive, since small DC voltages must be coupled to and measured on the charging conductors, wherein the voltage measurement must satisfy the insulation requirements, which in turn requires a complex circuit technology.

In addition, the time profile of the test voltage must be observed over a minimum time in order to be able to make a reliable statement about the absence of a discharge of the capacitor, as a result of which the conventional method is slow.

DE 10 2015 107 161 A1 describes a safety module which monitors a plurality of sensor values such as the temperature during the charging process. However, such monitoring is complicated, since a plurality of sensors must be installed and queried. In addition, the start of the charging process when a short circuit is present entails a considerable safety risk and a considerable risk of damage due to the high charging current.

### SUMMARY

In an embodiment, the present invention provides a device for monitoring a contact between charging conductors of a charging station for charging an electric vehicle, comprising: a signal generator configured to output an alternating test signal at the charging conductors; and an evaluation unit configured to determine, based upon the test signal, whether an electrically conductive contact exists between the charging conductors.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1 shows a schematic block diagram of a charging station with a device for monitoring a contact between charging conductors of the charging station according to a first exemplary embodiment;

FIG. 2 shows a schematic block diagram of a device for monitoring a contact between charging conductors according to a second exemplary embodiment;

FIG. 3 shows a schematic block diagram of a charging plug and a device for monitoring a contact between charging conductors according to a third exemplary embodiment;

FIG. 4 shows a schematic block diagram of a charging station, a charging plug, and a device for monitoring a contact between charging conductors according to a fourth exemplary embodiment; and

FIG. 5 shows a schematic block diagram of an embodiment of a filter element that can be used to delimit a test region in each exemplary embodiment.

### DETAILED DESCRIPTION

In an embodiment, the present invention provides a technology for reliably and quickly monitoring a short circuit between charging conductors.

Exemplary embodiments of the invention are described below with partial reference to the figures.

According to one aspect, a device for monitoring a contact between charging conductors of a charging station for charging an electric vehicle is provided. The device comprises a signal generator which is designed to output an alternating test signal to the charging conductors. Furthermore, the device comprises an evaluation unit which is designed to determine on the basis of the test signal whether an electrically conductive contact exists between the charging conductors.

The alternating test signal can be a signal which does not have only a direct voltage component (DC component)—for example, a signal which does not have a DC component. Alternatively or additionally, the alternating test signal can oscillate about a mean value—for example, be an alternating signal. For example, the alternating test signal can oscillate periodically or aperiodically. The average value can be equal to a ground potential.

The test signal can be a high-frequency signal. For example, the test signal can have a carrier frequency of at least one kilohertz (1 kHz) or at least 10 kHz. Furthermore, the test signal can be monochromatic or harmonic.

Alternatively or additionally, the test signal can have a distribution in the frequency domain (i.e., a power spectrum). For example, the test signal can comprise a pulse or a chirping (also referred to in technical jargon as “chirp”).

Each signal form (i.e., each carrier frequency or each distribution in the frequency domain) can also be recurring. Herein, the terms, “periodically” and “frequency” (in particular, the term, “high-frequency”), refer to the frequency of the test signal itself—for example, the carrier frequency of the test signal or the frequencies in the power spectrum of the test signal. Alternatively or additionally, a regularly recurring test signal can have a monitoring rate.

In comparison with conventional methods based upon a direct current component, the alternating test signal can be detected cost-effectively and reliably by the evaluation unit for determining the contact.

By outputting an alternating test signal, exemplary embodiments of the device can distinguish the test signal in the frequency domain from induced disturbances, thereby enabling a robust monitoring of the short circuit. Alternatively or additionally, the test signal can be limited, on account of a frequency-selective damping, to a specific test region along the charging conductor, as a result of which the monitoring of the short circuit is independent from components of the charging station or of the electric vehicle outside the test region.

The charging conductors can be combined in a charging cable connected to the charging station. A free end of the charging cable can have a charging plug. The charging plug can have contacts for each of the charging conductors.

The output of the test signal to the charging conductors can comprise an application of the test signal between the charging conductors or an application of the test signal on the charging conductors.

The electrically conductive contact (for short: the contact) between the charging conductors can also be referred to as a short circuit.

The test signal can be a voltage signal. The test signal can be an electrical voltage induced between the charging conductors.

A voltage (e.g., an amplitude of the voltage) of the test signal can be between 10 mV and 100 mV. For example, the voltage of the test signal during the output (e.g., during feeding) into the charging conductors can be transformed into a smaller voltage and transformed to a correspondingly higher voltage for determining the contact. By means of the coupling element, the voltages can be transformed—for example, only mV can be applied to the charging conductors. Preferably, the test signal can correspond to a hazardous contact low voltage between the charging conductors. The voltage of the test signal may be greater than 3 V or 12 V. Alternatively or additionally, a voltage of the test signal can be less than 24 V or 50 V.

The alternating test signal can be a voltage signal—for example, a periodic or oscillating profile of an electrical voltage. The test signal can also be referred to as a monitoring signal.

The voltage of the test signal (e.g., an amplitude of the alternating test signal) can be a fraction of a charging voltage for charging the electric vehicle. A frequency of the test signal can be different from a frequency of the charging voltage (e.g., 0 Hz for a DC charging current).

A frequency of the alternating test signal can be less than 100 MHz or 10 MHz. Alternatively or additionally, a frequency of the alternating test signal can be greater than 1 kHz or 10 kHz.

Alternatively or additionally, a wavelength (e.g., a first wavelength) of the test signal (preferably with respect to the charging conductor as the propagation medium of the test signal) can be greater—preferably several times greater—than a length of the charging conductor and/or the charging cable. Based upon the test signal, the evaluation unit can determine a (e.g., complex-valued) impedance between the charging conductors.

Alternatively or additionally, a wavelength (e.g., a second wavelength) of the test signal (preferably with respect to the charging conductor as the propagation medium of the test signal) can be smaller—preferably several times smaller—than a length of the charging conductor and/or the charging cable. The evaluation unit can be designed to determine a travel time of the test signal and/or a position of the contact (e.g., in response to the determination of the contact between the charging conductors). The position can be determined along the charging conductor and/or the charging cable based upon the running time and a group velocity of the test signal.

The alternating test signal can be a harmonic signal. Preferably, the test signal does not comprise a direct current component.

The signal generator may comprise an oscillator circuit.

The device can further comprise a coupling element that is connected between the signal generator and the charging conductor and is designed to output the test signal of the signal generator to the charging conductors. The coupling element can disconnect the charging conductors galvanically from one another and/or galvanically disconnect the charging conductors from the signal generator.

Because the alternating test signal to the charging conductors is output (e.g., by coupling) and measured, the insulation requirements can already be met by the coupling element—for example, without complex circuit technology. Alternatively or additionally, the coupling element can be designed to transform the voltage of the test signal.

The coupling element can couple the signal generator to the charging conductors capacitively or inductively for outputting the test signal of the signal generator to the charging conductors. Alternatively or additionally, the coupling element can comprise an impedance circuit.

The signal generator can be inductively and/or capacitively coupled to the charging conductors.

The device can comprise a control unit or be in signal connection with the control unit, or can be brought into signal connection with the same. The control unit can be designed to control or regulate the charging or discharging of the electric vehicle.

The device can comprise a control unit or a control interface connected or connectible to the control unit. The evaluation unit can further be designed to signal to the control unit or to the control interface whether the electrically conductive contact is present between the charging conductors.

The evaluation unit can be designed to signal a clearance for charging if there is no contact. Alternatively or additionally, the evaluation unit can be designed to signal a short circuit if the contact exists.

Alternatively or additionally, the signal generator and/or the evaluation unit can be in control communication with the control unit. The control unit can be designed to carry out or initiate the monitoring of the contact between the charging conductors before the charging of the electric vehicle.

The control unit can be designed to output a fault state and/or to interrupt a charging current through the charging conductor when the contact is present and/or to switch the charging conductor in a voltage-free mode.

The control unit can be designed to output the fault state as a warning signal (e.g., optically and/or acoustically and/or haptically). For example, the charging plug can comprise a vibration motor which is controlled by the control unit for outputting the haptic warning signal in response to the determination of the contact.

The control unit can be designed to electrically disconnect the charging conductors from a charging current source prior to outputting the test signal and/or determining whether there is contact between the charging conductors. Alternatively or additionally, the control unit can be designed to open a main relay and/or a charging relay of the charging station in response to determining that the contact exists between the charging conductors.

Alternatively or additionally, the control unit can be designed to electrically connect the charging conductors to the charging current source if there is no contact.

The charging current source may comprise a power conversion unit. The power conversion unit can be designed to output a charging current and/or a charging voltage to the charging conductors in accordance with the control unit. A main relay can selectively electrically disconnect and connect the charging current source and a power terminal of the control unit in, respectively, an open or closed state of the main relay. Alternatively or additionally, a charging relay can selectively electrically disconnect and connect the charging current source and the (preferably each of the) charging conductors in accordance with the control unit in, respectively, an open or closed state of the charging relay.

The control unit can be designed to carry out the output of the test signal and/or the determination of whether there is a contact by means of the signal generator or by means of the evaluation unit before the charging or discharging of the electric vehicle and/or while the charging conductors are electrically disconnected from the power conversion unit and/or before a signal conductor signals a connection between the charging station and the electric vehicle.

A test region for monitoring the contact between the charging conductors can be limited by means of electrical disconnection (e.g., by means of the open state of the charging relay) and/or by means of at least one frequency-selective filter element.

The at least one frequency-selective filter element can be arranged or interposed (e.g., on each of the charging conductors or together on the charging conductors) on the output side of the charging station (e.g., on the output side of the charging relay) and/or in the charging plug.

The frequency-selective filter element or at least one or each of the frequency-selective filter elements can enclose each or all the charging conductors with ferrites and/or comprise other frequency-selective components (e.g., inductors and capacitances with damping resistors).

The control unit can be designed to output, when the contact is present, a fault state of the charging cable or of the charging plug before a signal conductor of the charging cable or of the charging plug signals a connection between the charging station and the electric vehicle, and/or to output a fault state of the electric vehicle after a signal conductor of the charging cable or of the charging plug signals a connection between the charging station and the electric vehicle.

The evaluation unit can be designed to measure a current driven by the output test signal through the charging conductors. The evaluation unit can be designed to determine whether the contact exists between the charging conductors.

The evaluation unit can be designed to detect a voltage built up by the test signal between the charging conductors and/or a current driven by the test signal into the charging conductors, and to determine an impedance between the charging conductors based upon the voltage and/or the current. Alternatively or additionally, the evaluation unit can determine the existence of the contact between the charging conductors if the impedance (preferably an absolute value of the impedance or an active component of the impedance) is smaller than or greater than a threshold value of the impedance.

The evaluation unit can be designed to detect a damping of the test signal. Alternatively or additionally, the evaluation unit can determine the existence of the contact between the charging conductors if the damping is greater than or smaller than a threshold value of the damping.

The evaluation unit can be designed to measure a damping of the output test signal through the charging conductors. The evaluation unit can be designed to determine, based upon the measured damping, whether the contact exists between the charging conductors. The damping can be measured as a change in the test signal applied to an input and/or to an output of the coupling element.

The device for monitoring the contact can be arranged or implemented in the charging station.

According to a further aspect, a charging station for charging an electric vehicle is provided. The charging station comprises a charging current source and a charging relay which is designed to selectively electrically disconnect and connect the charging current source and the charging conductors of a charging cable to charge an electric vehicle in, respectively, an open or closed state of the charging relay. Furthermore, the charging station comprises a device for monitoring a contact between the charging conductors of the charging station according to one of the device aspects. Furthermore, the charging station comprises a control unit which is designed to output the test signal to the charging conductors in the open state of the charging relay by means of the signal generator of the device and to determine by means of the evaluation unit on the basis of the test signal whether an electrically conductive contact exists between the charging conductors. The control unit is further designed to output an error state when the contact is present and/or to close the charging relay for charging the electric vehicle when there is no contact.

The device for monitoring the contact can be arranged or implemented in the charging plug or in the charging cable.

According to a further aspect, a charging plug for charging an electric vehicle is provided. The charging plug comprises charging conductors, which are selectively electrically connected via a charging cable to a charging current source of a charging station, and a device for monitoring a contact between the charging conductors according to the device aspect.

In each aspect, the control unit can be arranged or implemented in the charging station and/or in the device for monitoring the contact and/or in the charging cable and/or in the charging plug.

In each aspect, the control unit for charging the electric vehicle can execute a charging method and/or control the charge current source. For example, the charging method may comprise querying signal conductors for enabling charging and/or determining a maximum charging current. Alternatively or additionally, the control of the charge current source can comprise regulating the charging current in the charging conductors and/or the charging voltage at the charging conductors.

Each aspect may further comprise features and functions disclosed in the context of one of the other aspects, or features and functions corresponding thereto.

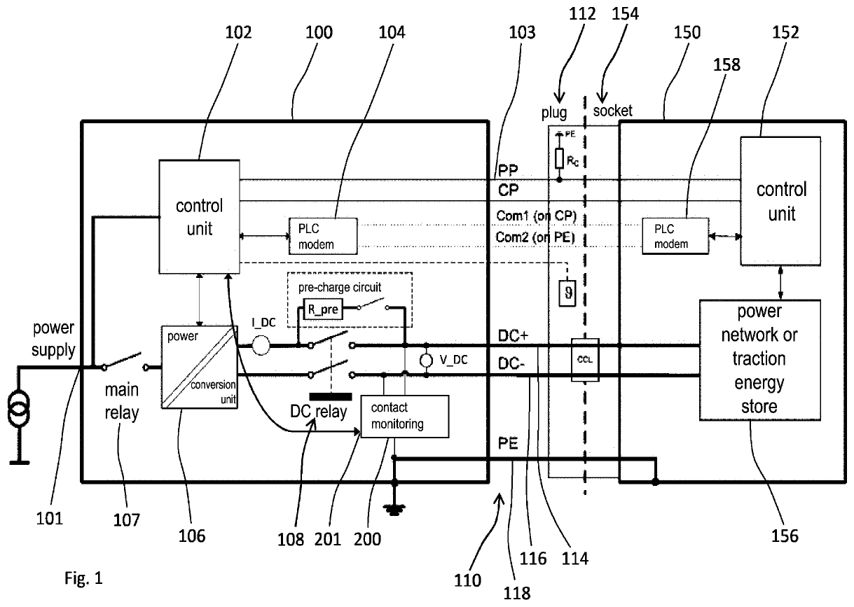

FIG. 1 shows a schematic block diagram of an exemplary embodiment of a charging station, generally designated by reference sign 100, for charging an electric vehicle 150 (for short: vehicle or EV). The charging station 100 can be designed, for example, as a wall charging station (also referred to as a “wallbox”) or as a charging column.

The charging station 100 comprises a control unit 102 which monitors or controls the charging operation. For example, the control unit 102 can be designed to control or regulate a profile of a charging current and/or a charging voltage.

In the exemplary embodiment shown in FIG. 1, charging is performed by direct current (DC). This exemplary embodiment of the charging station 100 and any exemplary embodiment disclosed herein can be modified for performing another charging method, e.g., for charging with AC voltage (AC)—in particular, with single-phase or multi-phase AC voltage. Alternatively or additionally, each exemplary embodiment can be designed to carry out a charging method according to IEC 62196.

The charging station 100 comprises a charging cable 110 with a plug 112, via the charging conductors 114 and 116 of which the charging station 100 provides the charging current to the EV 150. Furthermore, the charging station 100 provides a protective conductor 118 (PE) via the charging cable 110 and its plug 112 to the EV 150.

The EV 150 has a charging socket 154 complementary to the charging plug 112, which in the plugged-in state electrically conductively connects the charging conductors 114 and 116 to a power network 156 of the EV 150 and/or a traction energy store 156 of the EV 150—for example, for charging or discharging an electric traction energy store 156 installed in the EV 150. The traction energy store 156 can comprise a battery management system and a plurality of electrochemical secondary cells—preferably with lithium ions as mobile charge carriers.

The charging cable 110 further comprises signal conductors for signaling from the EV 150 to the charging station 100—preferably to the control unit 102 of the charging station 100. For example, the signal conductor 103 (which is also referred to in technical jargon as “proximity pilot” or PP) signals the connection between the charging station 100 and the EV 150. Optionally, the signal conductor PP signals the maximum load-bearing capacity of the cable 110 to the charging station 100. For this purpose, the EV 150 is provided with a resistance between PP and PE, the value of which indicates the load-bearing capacity. Via the signal conductor CP (in technical jargon, “control pilot”), the EV 150 signals to the charging station 100 the state (e.g., a charging clearance) of the EV 150—for example, depending upon the resistance between CP and PE.

Optionally, the control unit 102 comprises a modem 104 which is designed to communicate via the conductors CP and/or PE with a vehicle control unit 152 of the EV 150. The modem can modulate and demodulate communication signals with one or more carrier frequencies in each case on the conductors CP and/or PE, i.e., execute a carrier frequency communication (which is also referred to in technical jargon as “powerline communication” or PLC). The vehicle control unit 152 of the EV 150 comprises a corresponding vehicle modem 158.

If there is a short circuit between the charging conductors 114 and 116 (here, DC+ or DC−), which is caused, for example, by a defective charging cable 110 or conductive interference objects on the plug connectors 112 and 154 in the charging cable 110 or on the plug 112, the short circuit can, conventionally, not be detected immediately or before the charging process. Instead, in the plugged state of the plug 112 and the socket 162 on the EV 150, a possible short circuit must be indirectly detected with a complicated test (e.g., via the resistor R_pre of a pre-charge circuit) or, if this test is not implemented, activate protective elements such as fuses or circuit breakers.

The charging station 100 comprises an exemplary embodiment of a device generally designated by reference sign 200 for monitoring a contact (e.g., an impedance) between the charging conductors 114 and 116. The device 200 is designed to detect the contact (e.g., the impedance) between the charging conductors 114 and 116 to determine whether there is a contact—for example, whether the detected impedance indicates a short circuit or a faulty impedance.

A short circuit or a faulty impedance can be present, for example, if an amount of the impedance or a real component (also: active component) of the impedance is less than a threshold value of the impedance (i.e., a minimum value of the impedance).

The device 200 can be designed to output a fault state in response to the detected faulty impedance and/or to interrupt the charging current through the charging conductors 114, 116 and/or to switch the charging conductors 114, 116 in a voltage-free mode.

In one exemplary embodiment, the charging station 100 comprises a charging current source 106. The charge current source 106 can be a power conversion unit 106 which is designed to output—preferably in accordance with the control unit 102—the charging current and/or the charging voltage to the charging conductors 114 and 116. The power conversion unit 106 is fed by a power supply (e.g., external to the charging station 100) via a power terminal 101. For example, the power conversion unit 106 converts an alternating current provided by the power supply and/or at the power terminal 101 into a direct current as the charging current.

The charging station 100 comprises a main relay 107 that is designed to selectively electrically connect the power conversion unit 106 to the power supply and to electrically disconnect it from the power supply. Alternatively or additionally, the charging station 100 comprises a charging relay 108, which is designed to electrically connect the charging conductors 114 and 116 (preferably each) selectively to the power conversion unit 106 and to electrically disconnect them from the power conversion unit 106.

The device can be designed to open the main relay 107 and/or the charging relay 108 in response to the detected faulty impedance.

The device for monitoring an impedance can be realized as a monitoring of a contact between the charging conductors 114 and 116. Since a short circuit between the charging conductors 114 and 116 is an electrical contact, a short circuit can generally also be detected with the contact monitoring.

The signal generator 202 may comprise an oscillator circuit.

Preferably, the device 200 comprises an impedance circuit as a coupling element with a signal input to the signal generator 202 and a signal output to the charging conductors 114 and 116. The control unit 102 is designed to apply the test signal to the signal input as an excitation signal of the signal generator. The impedance circuit is designed to convert the excitation signal into the test signal to be output as a monitoring signal and to output the monitoring signal at the signal output for applying the charging conductors 114 and 116.

In each exemplary embodiment, the evaluation unit 204 can be designed to monitor a change in a signal applied to the impedance circuit and to determine the contact of the charging conductors 114 and 116 when the signal is changed. The present signal can be the excitation signal and/or the monitoring signal.

In one embodiment, the evaluation unit 204 can be designed to monitor a change in the excitation signal of the signal generator 202 applied to the coupling element (e.g., on the impedance circuit) and to determine the contact between the charging conductors 114 and 116 when the excitation signal is changed.

Alternatively or additionally, the evaluation unit 204 can be designed to detect a change in the monitoring signal.

Optionally, the control unit 102 can comprise, in addition to the coupling element (e.g., the impedance circuit), a further signal monitoring circuit for detecting a change in the monitoring signal. This signal monitoring circuit can be designed to detect a change in the monitoring signal by means of capacitive or inductive coupling.

Exemplary embodiments of the device 200 enable monitoring (preferably still before the charging process of electric vehicles 150) a possible short circuit in the charging conductors 114 and 116, i.e., to determine whether a short circuit is present (also: short circuit detection). A short circuit is an electrical contact between the charging conductors 114 and 116.

Exemplary embodiments of the device 200 can determine whether a short circuit exists before the charging operation—preferably before the charging plug 112 is plugged into the charging socket 154 of the vehicle 150. The device 200 is in principle suitable for the DC and AC charging and is independent of whether the energy flows from the charging station 100 to the vehicle 150 or vice versa (i.e., the vehicle 150 feeds energy into a network to which the charging station 100 is connected).

The short circuit determined between the charging conductors 114 and 116 can be caused in the charging cable 110 and/or in the plug 112. Alternatively or additionally, in the plugged-in state of the plug 112 of the charging station 100 and the charging socket 154 of the EV 150, the short circuit determined between the charging conductors 114 and 116 can be caused in the EV 150. A variant of each exemplary embodiment of the device 200 disclosed herein may be designed to determine short circuits that may occur in the EV 150 itself

The device 200 can be designed to distinguish between a short circuit in the charging cable 110 (or in the charging plug 112) and a short circuit in the EV 150, e.g., due to a signal transit time of a reflection of the test signal after the output, after the output of the test signal, and/or due to the signaling on the signal conductor 103. Optionally, for determining whether there is a short circuit in the EV 150, further components (e.g., filter elements) can be integrated into the EV 150. Alternatively, the device 200 can be designed to determine these short circuits as undifferentiated.

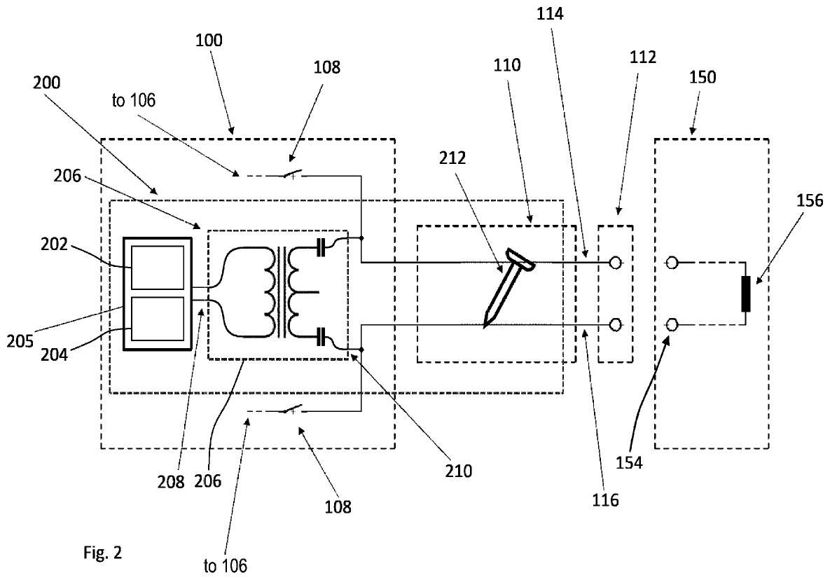

FIG. 2 shows a schematic block diagram of a second embodiment of the device 200 for monitoring a contact 212 between at least two charging conductors 114 and 116 for charging an electric vehicle 150. The second exemplary embodiment can be implemented for itself, or as a development of the first exemplary embodiment. Features which correspond or are interchangeable in different exemplary embodiments are provided with the same reference signs.

The device 200 comprises a contact monitoring circuit 205, viz., a (preferably integrated) unit with signal generator 202 and evaluation unit 204. The signal generator 202 may comprise an oscillator. The evaluation unit 204 can be a detector of the contact (i.e., a short circuit) between the charging conductors 114 and 116.

In the second exemplary embodiment of the device 200 shown in FIG. 2, the signal generator 202 and the evaluation unit 204 are arranged or implemented in the charging station 100.

By means of a coupling element 206, which can be implemented, for example, in the form of a transformer or transmitter, a test signal of the signal generator 202 applied to the signal input 208 of the coupling element 206 is applied to the charging conductors 114 and 116 via a signal output 210 of the coupling element 206. The charging conductors 114 and 116 carry the charging current (e.g., a DC or AC charging current) for the electric vehicle 150. By means of suitable dimensioning of the coupling element 206, insulation requirements between the controller 102 or the contact monitoring 200 and the charging conductors 114, 116 and/or between the charging conductors 114, 116 among one another can be fulfilled.

The charging conductors 114 and 116 are routed from the charging station 100, via the charging cable 110, to the charging plug 112, which is plugged into or can be plugged into the electric vehicle 150 in order to supply power to the battery 156 or the power unit 156 in the electric vehicle 150. The charging current for the charging process comes from the charging current source (e.g., the charging current source 106, the energy of which is fed via a power terminal 101). The release of the charging process can take place, for example, via the charging relay 108.

If there is now a short circuit 212 (in particular, for the first time)—here, for example, by a contact connection with a nail—the evaluation unit 204 determines that the short circuit 212 exists and can signal (preferably, report) the short circuit 212 as a fault state—for example, to the control unit 102.

The control unit 102 can perform, control, or initiate further actions subsequent to the signaling of the short circuit 212. By way of example, the control unit 102 cannot activate the charging process and/or output a fault state, e.g., as a signal tone, due to the open state of the charging relay 108.

Preferably, the coupling element 206 meets insulation requirements. For example, the coupling element 206 has a galvanic insulation between the contacts of the output 210 of the charging conductor 114, 116 and/or has a galvanic insulation between the input 208 and the output 210.

Preferably, the test signal is impressed on the charging conductors 114 and 116 via the coupling element 206 when the cable 110 is activated via the charging relay 108 acting as safety switch. If the cable 110 is then also not inserted into the vehicle 150 via the plug 112, no contact should be provided, and the test can take place.

Should a short circuit 212 (i.e., a contact) occur—here, for example, represented by a nail—which short circuits the charging conductors 114 and 116 in the cable 110, the contact monitoring circuit 205 can determine this in advance, and the charging process is not enabled.

Depending upon the length of the charging cable 110, it may be useful not to choose the frequency or the frequency spectrum of the test signal to be too high, e.g., to avoid natural resonances and/or irradiation effects on the charging cable 110, which can make a robust determination more difficult. For example, the frequency or the frequency spectrum of the test signal is selected such that the wavelength of the test signal on the charging conductors 114 and 116 is greater (preferably, significantly or several times larger) than the length of the charging cable 110 (e.g., as an actual or maximum length of the charging cable 110). In the case of a length of the charging cable 110 of a few meters, reasonable frequencies can lie in the kilohertz range or in the one-digit (maximum two-digit) megahertz range.

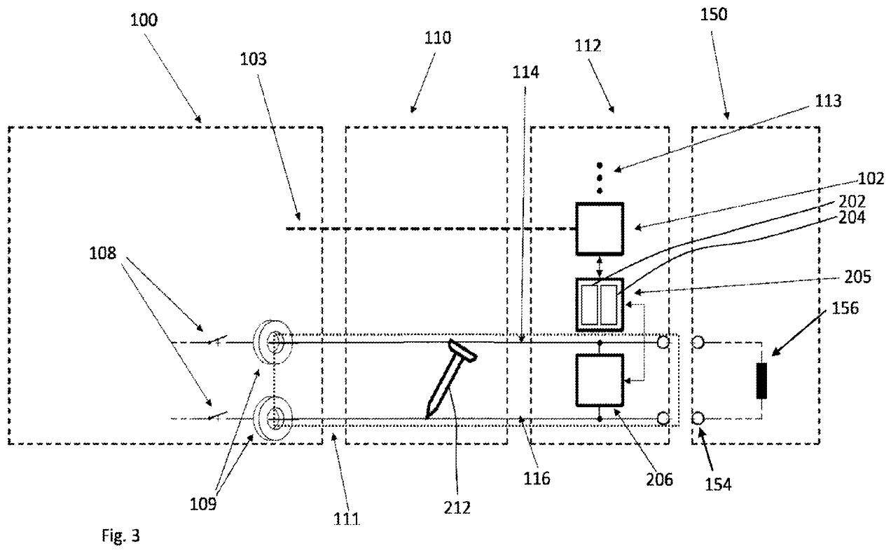

FIG. 3 shows a schematic block diagram of a third exemplary embodiment of the device 200 for monitoring a contact 212 between at least two charging conductors 114 and 116 for charging an electric vehicle 150. The third exemplary embodiment can be implemented for itself, or as a development of the first and/or the second exemplary embodiment. Features which are provided with the same reference signs in different exemplary embodiments can be equivalent, interchangeable, or coincident.

FIG. 3 shows a similar basic structure as in FIG. 2, wherein the charging station 100, the charging cable 110, the charging plug 112, and/or the vehicle 150 can each have one or more features which are described in the context of the first or second exemplary embodiment.

The third exemplary embodiment differs from the second exemplary embodiment in that the device 200—preferably the signal generator 202 and the evaluation unit 204 or the contact monitoring circuit 205—is accommodated or implemented in the charging plug 112, e.g., outside the charging station 100, in contrast to the second exemplary embodiment.

Due to the technology implemented in the charging plug 112, the third exemplary embodiment can be referred to as a charging plug for monitoring a short circuit or as an intelligent charging plug 112.

The control unit 102, which is preferably implemented in the charging plug 112 (e.g., as part of the device 200), can be designed for signaling to the charging station 100 or for communication with the charging station 100. Alternatively or additionally, the control unit 102 can be used to output the test signal by means of the signal generator and/or control or initiate the determination of whether there is a contact 212 by means of the evaluation unit 204. Optionally, the control unit 102 may control charging (or discharging).

That is to say, the control of the charging can be implemented in the charging station 100 by means of a separate control unit, or the control unit 102 also executes this function in the charging plug 112.

The third exemplary embodiment can preferably be realized when electronic components 113 are already located in the charging plug 112 anyway, such as, for example, the control unit 102 (preferably a processor, which can be a microprocessor, for example, with a memory or a microcontroller).

Alternatively or additionally, the device 200—in particular, the control unit 102 in the device 200—is connected to the charging station 100, via further signal conductors 103, with data interfaces and/or, via supply conductors 103, for energy supply (e.g., with 12 V or 24 V). As a result, the signal generator 204 of the device 200 can also be controlled in the charging plug 112, and the test signal (i.e., a short-circuit detection signal), which is sent for determination (i.e., for short-circuit detection), via the coupling element 206 and the evaluation unit 204, to the device 200, can be evaluated and transmitted to the charging station 100.

Further components 113 can be accommodated in the charging plug 112. The further components 113 can comprise, for example, a power supply unit for supplying power to the controller 102 and/or the signal generator 202 and/or the evaluation unit 204. Alternatively or additionally, the further components 113 can comprise a temperature monitoring unit for monitoring a temperature of the charging conductors 114 and 116.

In order to define a test region 111 (e.g., a portion of the charging cable 110 and/or the plug 112) for which the determination occurs as to whether there is a contact (i.e., the short-circuit detection or short-circuit test), at least one of the following measures can be implemented. A first measure is to output the test signal and/or to carry out the short-circuit test only when the charging plug 112 is not inserted into the vehicle 150 (i.e., into the charging socket 154). The control unit 102 can be designed to detect the unconnected or unplugged state, e.g., due to the signaling (preferably a detection of a resistance value) on the signal conductor 103 (e.g., on the signal conductor PP of the first exemplary embodiment). A corresponding resistor can be connected between PP and PE in the vehicle 150. A second measure is to open the charging relay 108 (i.e., the relay contacts of the charging relay 108 are disconnected) so that the test region 111, which is tested for short circuits, is limited in a defined manner to the charging station 100, since each of the charging conductors 114 and 116 is galvanically disconnected. In the case of a combination of the first measure and the second measure, the test region of each of the charging conductors 114 and 116 is delimited on both sides by the respective galvanic disconnection, whereby precisely this test region 111 is monitored up to the galvanic disconnection.

An alternative to opening the charging relay or charging relays 108 is to define or delimit the test region 111 (e.g., to the charging station 100) by connecting or arranging filter elements 109 (e.g., a low-pass filter) on the output side of the one or more charging relays 108 at each of the charging conductors 114 and 116.

For example, the filter elements can be low-pass filter elements 109. The low-pass filter elements 109 can comprise ferrites. In FIG. 3, the filter elements 109 are designed as toroidal cores or as flap ferrites, which are each placed around the charging conductors 114 and 116, for example.

The low-pass filter elements 109 can be very low-impedance for the charging current (e.g., a DC charging current or a low-frequency AC charging current). The frequency or the frequencies or the frequency spectrum of the test signal as a contact monitoring signal are designed such that the low-pass filter elements 109 are high-impedance for the test signal. For example, any wiring which is arranged behind the filter elements 109 (e.g., in the charging station 100) from the perspective of the charging cable 110 is thereby unable to influence the test signal.

In other words, if there is a short circuit in FIG. 3 on the left-hand side next to the filter elements 109 (e.g., ferrites), this is excluded during determination by means of the evaluation unit 204 (i.e., is explicitly not detected by the short-circuit detection). Determining whether there is a contact refers only to a contact in the test region 111 between the filter elements 109 and the unconnected or not plugged-in charging plug 112. Precisely this behavior can be desired, so that defined conditions are effective, and an arbitrary connection within the charging station 100 cannot impair the functionality of the device 200 (i.e., the short-circuit monitoring).

Furthermore, it may be expedient to carry out the short-circuit monitoring only in the exposed region outside the charging station 100. For example, the filter elements 109 can be placed as close as possible to a terminal region of the charging cable 110 within the charging station 100.

The filter elements 109, which can consist of magnetic material, for example, can be saturated with large charging currents, depending upon the dimensioning, and thus temporarily lose their filter effect. Therefore, the control unit 102 is preferably designed to carry out or initiate the short-circuit monitoring by means of signal generator 202 and evaluation unit 204 when no charging current or no large charging current flows, and the filter elements 109 are not loaded or not strongly loaded.

A short circuit occurring during the charging process can or should be disconnected as quickly as possible by means of other devices than the device 200 (e.g., fuses), so that no dramatic effects can occur due to the short circuit during charging. For this application case (i.e., a short-circuit detection and safety shutdown during the charging process), the device 200 can, optionally, be usable.

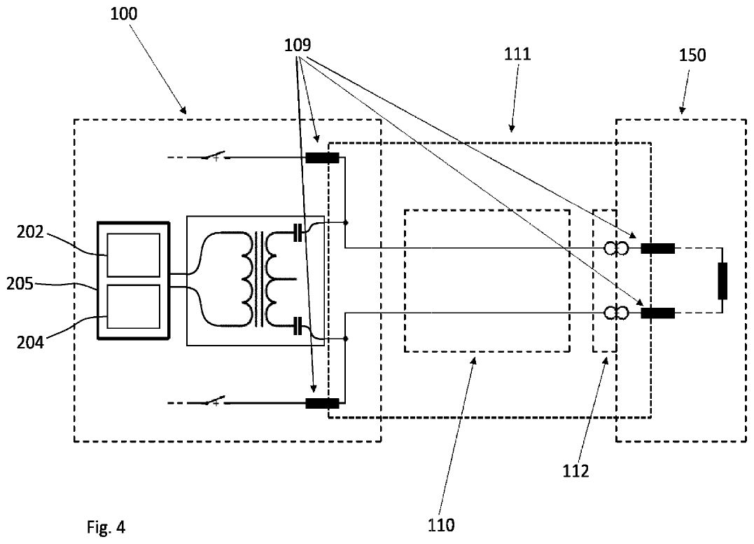

FIG. 4 shows a schematic block diagram of a fourth embodiment of the device 200 for monitoring a contact 212 between at least two charging conductors 114 and 116 for charging an electric vehicle 150. The fourth exemplary embodiment can be implemented for itself, or as a development of the first, second, and/or third exemplary embodiment. Features which are provided with the same reference signs in different exemplary embodiments can be equivalent, interchangeable, or coincident.

In the fourth exemplary embodiment, the device 200 (i.e., the monitoring device) is implemented or accommodated in the charging station 100 (preferably, as in the second exemplary embodiment). The device 200 comprises a total of four or at least four filter elements 109. For example, a filter element 109 for delimiting the charging station 100 (e.g., on the one or more charging relays 108) and for delimiting the EV 150 (e.g., in the charging plug 112) is arranged on each charging conductor 114 and 116.

In the fourth exemplary embodiment, the device 200 can determine whether there is a contact (i.e., defined states can be determined for the test region 111 to be monitored), even if the charging plug 112 is plugged into the vehicle 150 (i.e., into the charging socket 154). Optionally, the filter elements 109 can be arranged to delimit the EV 150, or further filter elements 109 can be arranged in the EV 150.

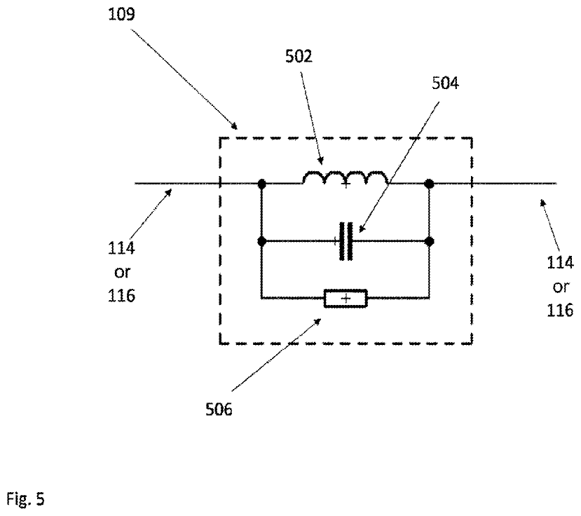

FIG. 5 shows a schematic block diagram of an embodiment of a filter element 109. The embodiment of the filter element 109 can be used in any exemplary embodiment disclosed herein—preferably as a low-pass filter, high-pass filter, band-pass filter, or band-lock barrier.

The filter element 109 comprises an inductance 502, a capacitance 504, and a damping resistor 506. The filter element 109 can be connected to the charging conductor 114 and/or 116. For the low frequencies of the charging current, the inductance acts at low impedance, so that (e.g., almost) the entire charging current flows through the inductance 502. Here, the possible loss resistance of the inductance must be kept low enough that no significant losses, and thus heating during the charging process, result. The inductance 502 can comprise a coil. Alternatively or additionally, a line inductance of a line segment of the charging conductor 114 or 116 can be used as an inductance.

The capacitance 504 and the damping resistor 506 can be selected such that, at the frequency of the test signal (i.e., the short-circuit monitoring signal), a band lock results, i.e., the total impedance of the filter element 109 is large for the test signal (e.g., in comparison with the impedance for the charging current). Thus, the limitation (i.e., a block) of the test signal and thus a defined test range 111 (also: monitoring region) can be provided.

The filter element can comprise, for example, a parallel resonant circuit, the resonant frequency of which is the frequency (also: working frequency or frequency spectrum) of the test signal.

While ferrites and/or parallel oscillating circuits are advantageous (e.g., compact, reliable, and/or precisely tunable) embodiments of the filter elements 109, there are further possibilities for implementing the filter elements 109.

As has been apparent from the above exemplary embodiments, at least individual exemplary embodiments can implement safety monitoring, e.g., determining whether a contact exists between charging conductors 114 and 116 (i.e., the detection of a short circuit)—for example, in charging cable 110 before the charging operation is enabled. Thus, possible short-circuits (e.g., caused by vandalism—for example, if someone pushes a conductive object such as a paper-clip into the contacts of the charging plug 112) can be determined immediately after the occurrence of the short-circuit, and are preferably reported to the control unit 102.

The monitoring takes place with low voltages which are not hazardous to touch, so that there is no danger even in the case of a deliberately induced short circuit, since the actual charging voltage is not yet present at the externally accessible contacts. The safety of the overall system can furthermore be increased by the optional galvanic disconnection of the coupling element 206.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE SIGNS

charging station 100
power terminal of the charging station 101
control unit 102
signal conductor, e.g., PP or CP, or supply conductor 103
modem of control unit 104
charging current source - preferably power conversion unit106
main relay 107
charging relay 108
filter elements 109
charging cable110
test region 111
charging plug of the charging cable 112
further components in the charging plug 113
first charging conductor, e.g., positive pole 114
second charging conductor, e.g., minus pole116
safety conductor 118
electric vehicle (EV) 150
vehicle control unit of EV 152
charging socket of EV 154
power network or traction energy store of EV 156
vehicle modem of EV 158
device for monitoring a contact 200
interface to the control unit of the charging station 201
signal generator 202
evaluation unit 204
contact monitoring circuit 205
coupling element 206
input of the coupling element208
output of the coupling element 210
contact or short circuit between charging conductors 212

1. A device for monitoring a contact between charging conductors of a charging station for charging an electric vehicle comprising:
a signal generator configured to output an alternating test signal at the charging conductors; and
an evaluation unit configured to determine, based upon the test signal, whether an electrically conductive contact exists between the charging conductors.

2. The device of claim 1, wherein the test signal comprises a voltage signal.

3. The device of claim 1, wherein the test signal is aperiodic or periodic, and/or
wherein a wavelength of the test signal on the charging conductors is greater than a length of the charging conductors.

4. The device of claim 1, wherein the signal generator comprises an oscillator circuit.

5. The device of claim 1, further comprising:
a coupling element, connected between the signal generator and the charging conductors, configured to output the test signal of the signal generator to the charging conductors,
wherein the coupling element galvanically insulates the charging conductors from one another and/or galvanically insulates the charging conductors from the signal generator.

6. The device of claim 5, wherein the coupling element couples the signal generator capacitively and/or inductively to the charging conductors for outputting the test signal of the signal generator to the charging conductors, and/or
wherein the coupling element comprises an impedance circuit and/or a transformer and/or a transmitter.

7. The device of claim 1, further comprising:
a control unit or a control interface connected or connectable to the control unit,
wherein the evaluation unit is configured to signal to the control unit or to the control interface whether there is a contact between the charging conductors of the electrically conductive contact.

8. The device of claim 7, wherein the control unit is configured to output a fault state and/or to interrupt a charging current through the charging conductors when the contact is present and/or to switch the charging conductors in a voltage-free mode.

9. The device of claim 7, wherein the control unit is configured to:
electrically disconnect the charging conductors from a charging current source prior to outputting the test signal and/or determine whether a contact exists between the charging conductors; and/or
electrically connect the charging conductors to the charging current source if there is no contact.

10. The device of claim 9, wherein the charge current source comprises a power conversion unit configured to output, in accordance with the control unit, a charging current and/or a charging voltage to the charging conductors,
wherein a main relay selectively electrically disconnects and connects the charging current source and a power terminal in accordance with the control unit in, respectively, an open or closed state of the main relay; and/or
wherein a charging relay selectively electrically disconnects and connects the charging current source and each of the charging conductors in accordance with the control unit in, respectively, an open or closed state of the loader relay.

11. The device of claim 1, wherein a test region for monitoring the contact between the charging conductors is limited by electrical disconnection and/or at least one frequency-selective filter element.

12. The device of claim 11, wherein the at least one frequency-selective filter element is arranged or interposed on each of the charging conductors or jointly on the charging conductors on the output side of the charging station and/or in the charging plug.

13. The device of claim 11, wherein the at least one frequency-selective filter element envelopes the charging conductors in each case or together with ferrites and/or comprises a parallel resonant circuit with damping resistor and/or frequency-selective arrangements of inductances and/or capacitances with damping resistors.

14. The device of claim 7, wherein the control unit is configured to output, when the contact is present, a fault state of the charging cable or of the charging plug before a signal conductor of the charging cable or of the charging plug signals a connection between the charging station and the electric vehicle, and/or output a fault state of the electric vehicle after a signal conductor of the charging cable or of the charging plug signals a connection between the charging station and the electric vehicles.

15. The device of claim 1, wherein the evaluation unit is configured to detect a voltage built up by the test signal between the charging conductors and/or a current driven by the test signal in the charging conductors, and to determine an impedance between the charging conductors based upon the voltage and/or the current, and
wherein the evaluation unit determines an existence of the contact between the charging conductors if the impedance is less than or greater than a threshold value of the impedance.

16. The device of claim 1, wherein the evaluation unit is configured to detect a damping of the test signal, and
wherein the evaluation unit is configured to determine an existence of the contact between the charging conductors if the damping is greater than or less than a threshold value of the damping.

17. A charging station for charging an electric vehicle, comprising:
a charging current source;
a charging relay configured to selectively electrically disconnect and connect the charging current source and the charging conductors of a charging cable for charging an electric vehicle in, respectively, an open or closed state of the charging relay;
the device of claim 1; and
a control unit configured to output, in the open state of the charging relay, the test signal to the charging conductors by the signal generator of the device and, based upon the test signal, determine by the evaluation unit whether there is an electrically conductive contact between the charging conductors,
wherein the control unit is configured to output a fault state when the contact is present and/or to close the charging relay for charging the electric vehicle when there is no contact.

18. A charging plug for charging an electric vehicle, comprising:
a charging conductor selectively electrically connected to a charging current source of a charging via a charging cable; and
the device of claim 1.

19. The device of claim 2, wherein the voltage signal comprises an electrical voltage induced between the charging conductors and/or a voltage greater than 10 mV, 3 V, or 12 V and/or less than 100 mV, 24 V, or 50 V.

20. The device of claim 3, wherein a frequency of the test signal is less than 100 MHz or 10 MHz and/or greater than 1 kHz or 10 kHz.
